(19) United States
(12) Patent Application Publication
(10) Pub. No.: US 2010/0061141 A1
(43) Pub. Date: Mar. 11, 2010

(54) Non-volatile memory device and storage system including the same

(75) Inventor: Young Nam Hwang, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/461,990

(22) Filed: Aug. 31, 2009

(30) Foreign Application Priority Data
Sep. 5, 2008 (KR) 10-2008-0087896

(51) Int. Cl. G11C 11/00; G11C 7/02; G11C 7/10

(52) U.S. Cl. 365/148; 365/210.1; 365/189.04

(57) ABSTRACT

A non-volatile memory device may include a plurality of data cells, each data cell of the plurality of data cells programmed to have a first resistance variation among a plurality of first resistance variations; and a plurality of reference cells, each reference cell of the plurality of reference cells programmed to have a second resistance variation among a plurality of second resistance variations. A change in a resistance of the data cells is used to identify a level of data programmed to memory. Because the resistance variation of the data cells may change with time or due to changes in temperature, a reference cell is also included in the non-volatile memory device. The reference cell is used for effective reading of the data value of a corresponding data cell. A storage system may include the non-volatile memory device.

### FOREIGN PRIORITY STATEMENT

This application claims priority under 35 U.S.C. §119 to Korean Patent Application No. 10-2008-0087896, filed on Sep. 5, 2008, in the Korean Intellectual Property Office (KIPO), the entire contents of which are incorporated herein by reference.

### BACKGROUND

Example embodiments relate to a non-volatile memory device and a storage system including the same.

The demand for a high density/integration random access semiconductor device, for example, flash memory used in portable electronic equipment, is ever increasing. Recent research has proposed replacing the capacitor in a dynamic random access memory (DRAM) with a non-volatile material, e.g., a resistive material.

Examples of such resistive memory including a resistive material are ferroelectric RAM (FRAM) using ferroelectrics, magnetic RAM (MRAM) using a tunneling magneto-resistive film, phase change memory devices using chalcogenide alloys and the like. Generally, phase change memory devices may be manufactured with higher integration using relatively simple procedures at low cost and are thus highly likely to be next-generation universal memory.

Technology for storing data of at least two bits in a single memory cell in phase change memory devices has been developed. The memory cell in the technology is referred to as a multi-level cell (MLC). However, since a resistor range which the MLC has at each level varies with time or temperature, a high-precision read circuit or algorithm is required to accurately read data programmed to the MLC. In addition, a circuit or device for accurately distinguishing the different magnitudes of a resistive element in a phase change memory device is needed.

### SUMMARY

According to an example embodiment a non-volatile memory device may include a plurality of data cells, each of the plurality of data cells programmed to have a first resistance variation among a plurality of first resistance variations, and a plurality of reference cells, each of the plurality of reference cells programmed to have s second resistance variation among a plurality of second resistance variations.

According to an example embodiment, if each of the data cells is an N-bit multi-level cell, each reference cell may be programmed to have a second resistance variation among (2^{N}−1) second resistance variations, where N is a natural number. The reference cells may be further programmed to have different resistance variations and at least one second resistance variation may exist between two adjacent first resistance variations.

According to an example embodiment the data cells and the reference cells may be resistive memory cells. The data cells and the reference cells may be simultaneously programmed.

According to an example embodiment the non-volatile memory device may further include a sense amplifier circuit configured to compare a signal corresponding to a resistance of at least one data cell with a signal corresponding to a resistance of at least one reference cell and output a logic signal based on the comparison result.

According to an example embodiment the non-volatile memory device may further include an enable signal generation circuit configured to generate at least one enable signal to sequentially output the signal corresponding to the resistance of the at least one reference cell to the sense amplifier circuit.

According to an example embodiment the enable signal generation circuit may control an output timing of at least one enable signals to first output the signal corresponding to the resistance value of the reference cell having an intermediate resistance variation to the sense amplifier circuit.

According to an example embodiment a storage system may include a non-volatile memory device and a processor configured to control operations of the non-volatile memory device. The non-volatile memory device may include a plurality of data cells, each of the plurality of data cells programmed to have a first resistance variation among a plurality of first resistance variations, and a plurality of reference cells, each of the plurality of reference cells programmed to have s second resistance variation among a plurality of second resistance variations.

According to an example embodiment the storage system may further include a wireless interface connected with the processor. The storage system may further include an input/output interface connected with the processor. The data cells and the reference cells of the example storage system may be resistive memory cells.

### BRIEF DESCRIPTION OF THE DRAWINGS

The above and other features and advantages of example embodiments will become more apparent by describing in detail an example embodiment with reference to the attached drawings. The accompanying drawings are intended to depict an example embodiment and should not be interpreted to limit the intended scope of the claims. The accompanying drawings are not to be considered as drawn to scale unless explicitly noted.

FIG. 1 is a graph showing variation of resistance of data cells and variation of resistance of reference cells according to an example embodiment;

FIGS. 2A through 2C illustrate various configurations of reference cells and data cells according to an example embodiment;

FIG. 3A illustrates change in resistance of data cells due to increase in temperature and FIG. 3B illustrates change in resistance of reference cells with time, according to an example embodiment;

FIG. 4 illustrates a circuit diagram of a non-volatile memory device according to an example embodiment;

FIG. 5 illustrates a method of setting a reference voltage for programming a reference cell according to an example embodiment;

FIG. 6 is a table showing the number of reference cells, overhead, write buffer, time, and read current in each case when a unit of a simultaneous write and verify (W & V) operation changes in a non-volatile memory device according to some embodiments of the present invention;

FIG. 7A illustrate a circuit for reading a programmed data cell and FIG. 7B illustrates a timing diagram of an enable signal generation circuit in a non-volatile memory device according to an example embodiment;

FIGS. 8A and 8B illustrate reading data using interchangeable resistance variations in a non-volatile memory device according to an example embodiment;

FIGS. 9A and 9B illustrate a reduction in the number of reference cells according to an example embodiment; and

FIG. 10 is a block diagram of a storage system including a non-volatile memory device according to an example embodiment.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

A phase change memory cell may include a resistive element and a switching element. The resistance of the resistive element may be controlled based on the amount of current, voltage and/or laser beam applied to the memory cell. For instance, if the resistance varies with a current supplied to a phase change material, the resistance value may be determined based on the amplitude, duration and/or falling time of the current. The switching element may be implemented using a transistor or diode, for example.

The resistance element may include a phase change material and may be either in a crystalline state or an amorphous state based on the amount of applied energy (i.e. current, voltage, laser beam, or the like). In addition, the resistance of the phase change memory cell may be determined based on the amount of amorphous material contained in the phase change material. For instance, the greater the amount of amorphous material, the greater the resistance of the phase change memory cell. A multi-level cell (MLC) cell, according to an example embodiment, may occupy an intermediate state in addition to the crystalline state and the amorphous state. The intermediate state may be generated by adjusting the amount of amorphous material.

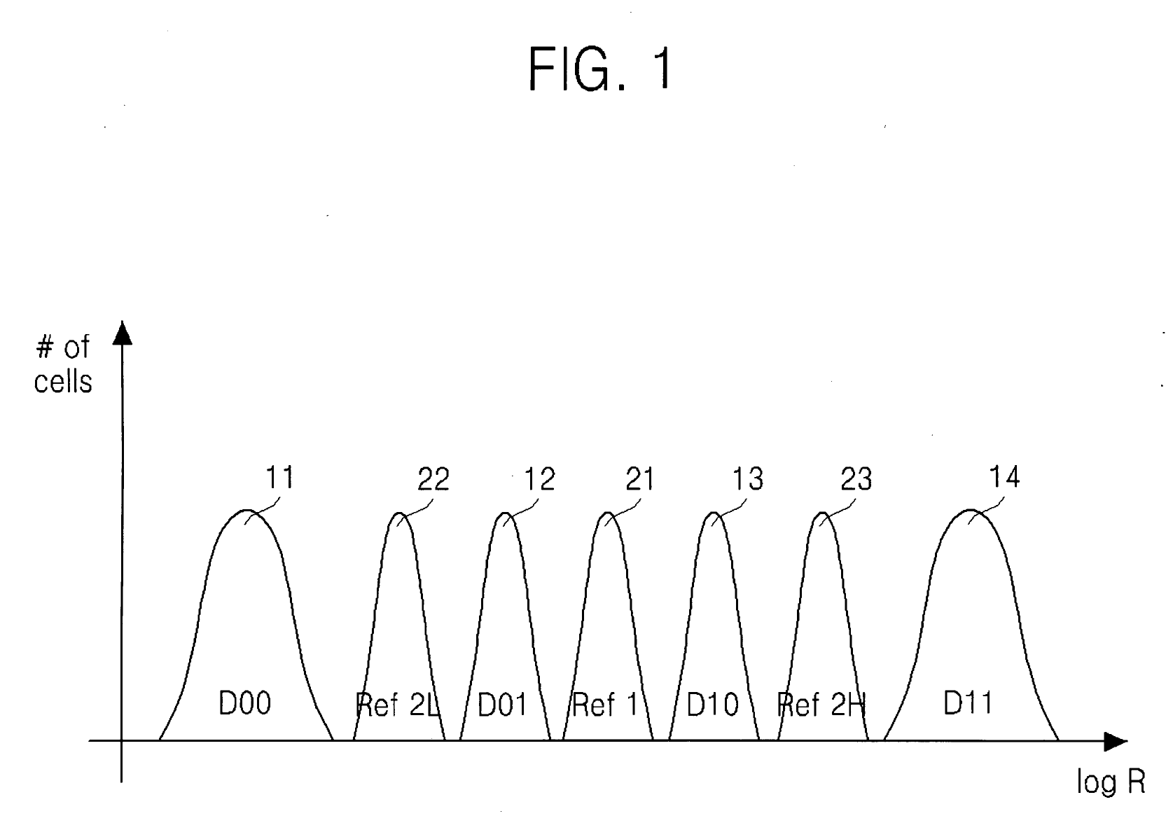

FIG. 1 is a graph showing resistance variations 11, 12, 13, and 14 of data cells and resistance variations 21, 22, and 23 of reference cells according to an example embodiment. In a non-volatile memory device, according to an example embodiment, a single cell may be implemented by an N-bit MLC, where N is a natural number. For relative ease of description, it is assumed that the cell is 2-bit MLC.

When a memory cell is implemented by a 2-bit MLC, 4 (=2²) different resistance variations may be possible in the cell memory. As mentioned above, the resistance variations may be realized by adjusting the amount of amorphous material contained in a phase change material. As an example, the four resistance variations 11 through 14 are illustrated in FIG. 1. A data stored in the data cells may be programmed to have one of the resistance variations 11 through 14. As described above, since a resistance of the phase change memory cell increases with the amount of amorphous material contained in the phase change material, the first resistance variation 11 may indicate a crystalline state having a lower amount of amorphous material and the resistance may be lower. The fourth resistance variation 14 may indicate an amorphous state having a higher amount of amorphous material and the resistance may be higher. To ensure a read margin, as illustrated in FIG. 1, each of the resistance variations 11 through 14 may have non-overlapping resistance ranges.

The non-volatile memory device, according to an example embodiment, may also include a plurality of reference cells in order to better identify the resistance variation data read from a data cell. The reference cells may be programmed to have different resistance variations than the data cells. A resistor range corresponding to the resistance variation of the reference cells may not overlap with a resistor range corresponding to the resistance variation of the data cells.

As illustrated in FIG. 1, a resistance range of the reference cells may be between the resistance ranges of the data cells. For instance, a resistance range of the first reference resistance variation 21 is between the second resistance variation 12 and the third resistance variation 13, a resistance range of the second reference resistance variation 22 is between the first resistance variation 11 and the second resistance variation 12, and a resistance range of the third reference resistance variation 23 is between the third resistance variation 13 and the fourth resistance variation 14. To ensure a read margin, resistance ranges of adjacent resistance variations may not overlap with each other.

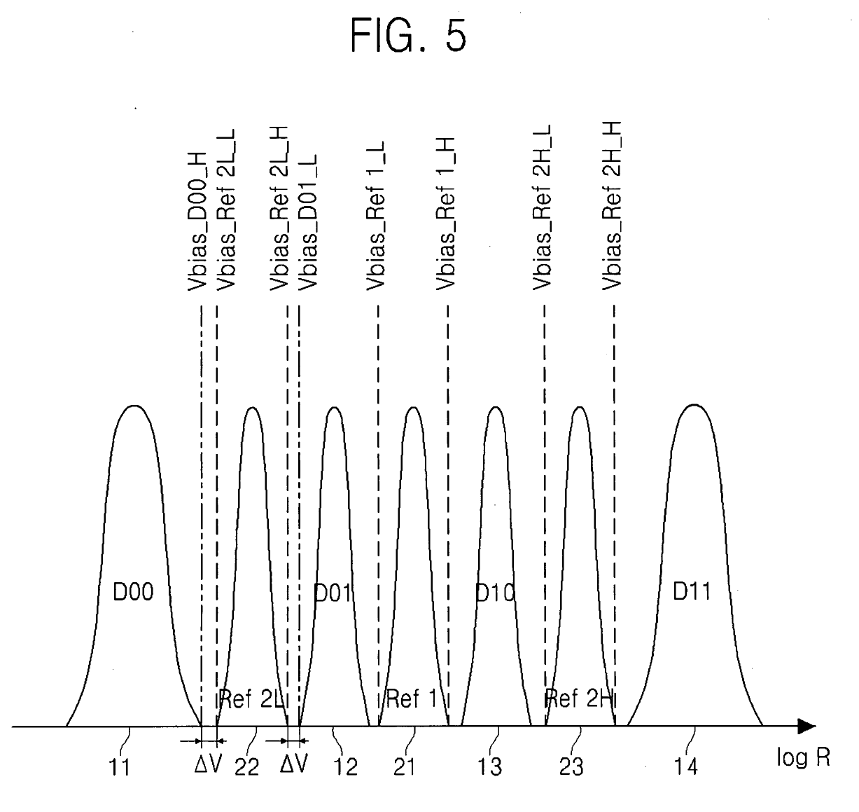

The data cells and the reference cells may be connected to a word line and may be simultaneously programmed. In addition, upon programming, the reference cells may also be verified to ensure their programming with a desired resistance range. The verification may be performed based on a bias voltage corresponding to each of the resistance variations 11 through 14, which is described below with reference to FIG. 5.

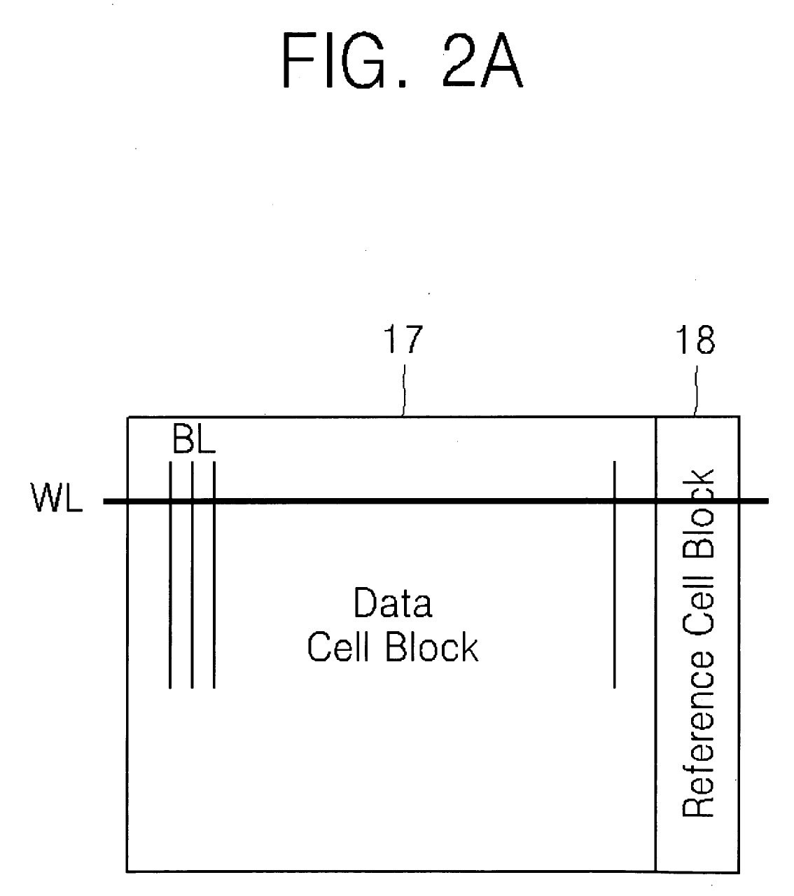

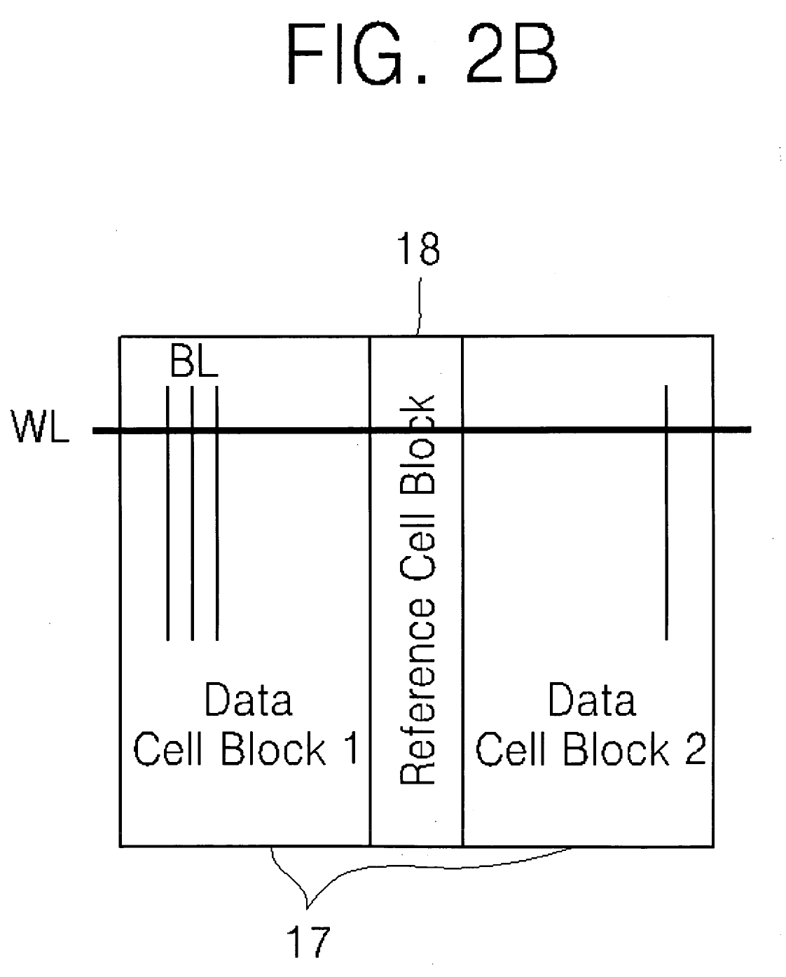

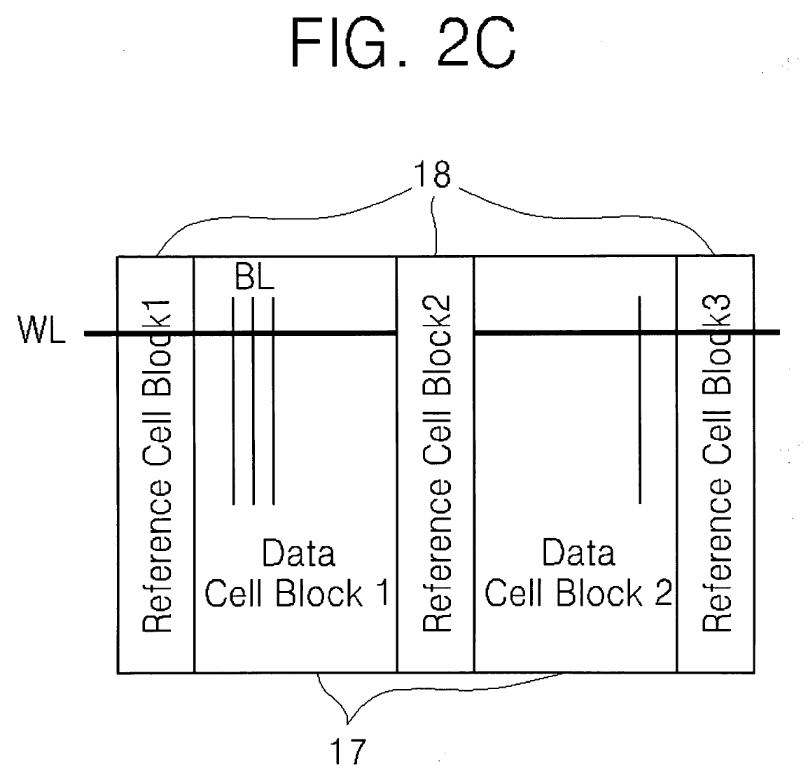

FIGS. 2A through 2C illustrate various configurations of reference cells and data cells according to an example embodiment. A non-volatile memory device may include a data cell block 17 including a plurality of data cells and a reference cell block 18 including a plurality of reference cells. In the non-volatile memory device, programming (or writing), reading, and verification may be performed in a word line unit and a reference cell may be positioned at an arbitrary portion of a word line.

Referring to FIG. 2A, the reference cell block 18 may be positioned on one side of the data cell block 17, for example. Referring to FIG. 2B, the reference cell block 18 may be positioned at the center of the data cell block 17. Referring to FIG. 2C, the reference cell block 18 may divided into a plurality of sections and each of the sections may be positioned at an arbitrary location. Accordingly, a non-volatile memory device may adapt to various environments by adjusting the arrangement of the reference cells as required.

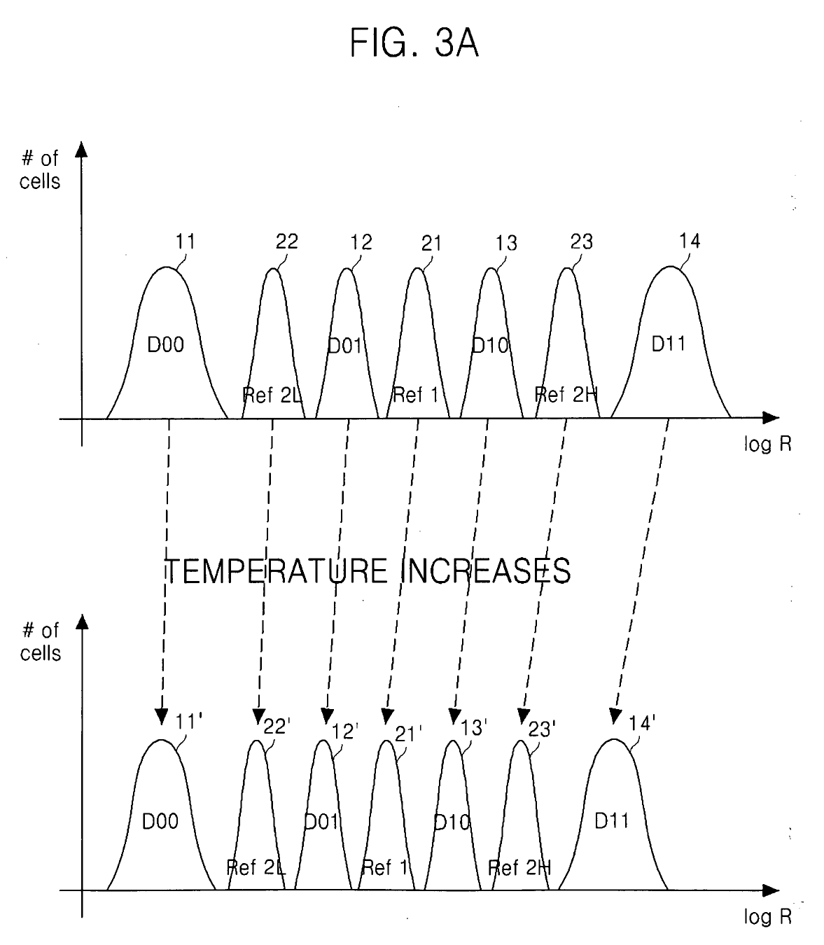

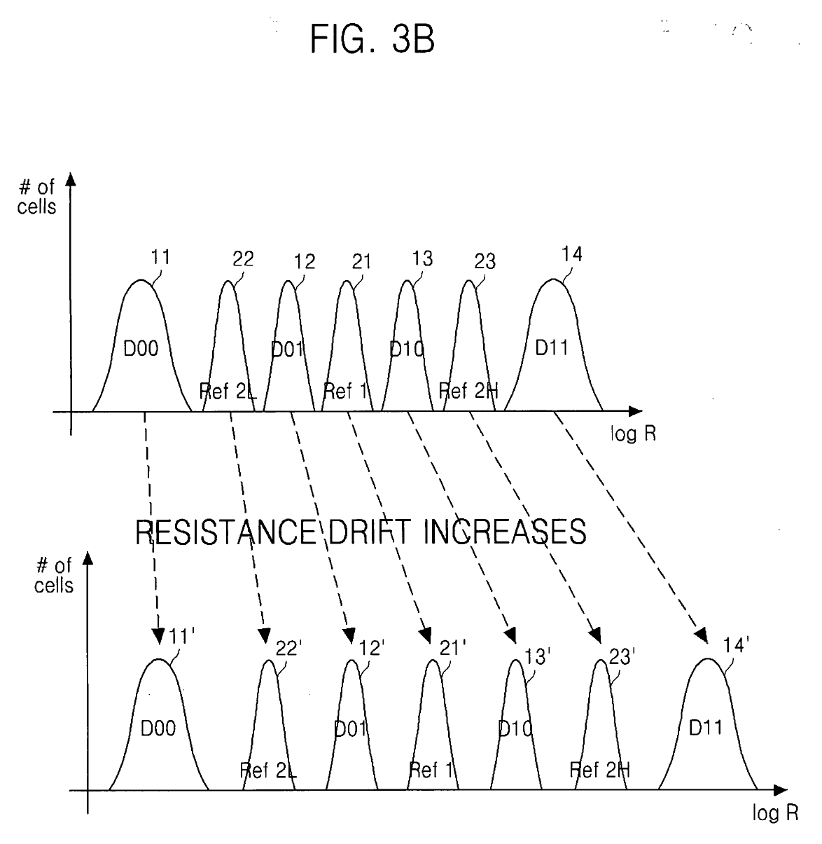

FIG. 3A illustrates the change in resistance of data cells with change in temperature and FIG. 3B illustrates change in resistance of reference cells with time. Referring to FIG. 3A, when temperature increases, a resistance range of the resistance variations 11 through 14 and 21 through 23 changes to a resistance range corresponding to resistance variations 11′ through 14′ and 21′ through 23′. However, the order of resistance values remains unchanged.

Referring to FIG. 3B, after data programming (or writing), the resistance variations 11 through 14 and 21 through 23 may changes into resistance variations 11′ through 14′ and 21′ through 23′ with time, However, the order of resistance values remains unchanged. Because, the order of resistance values does not change with time and with an increase in temperature, the data corresponding to the resistance variations 11 through 14 may be identified.

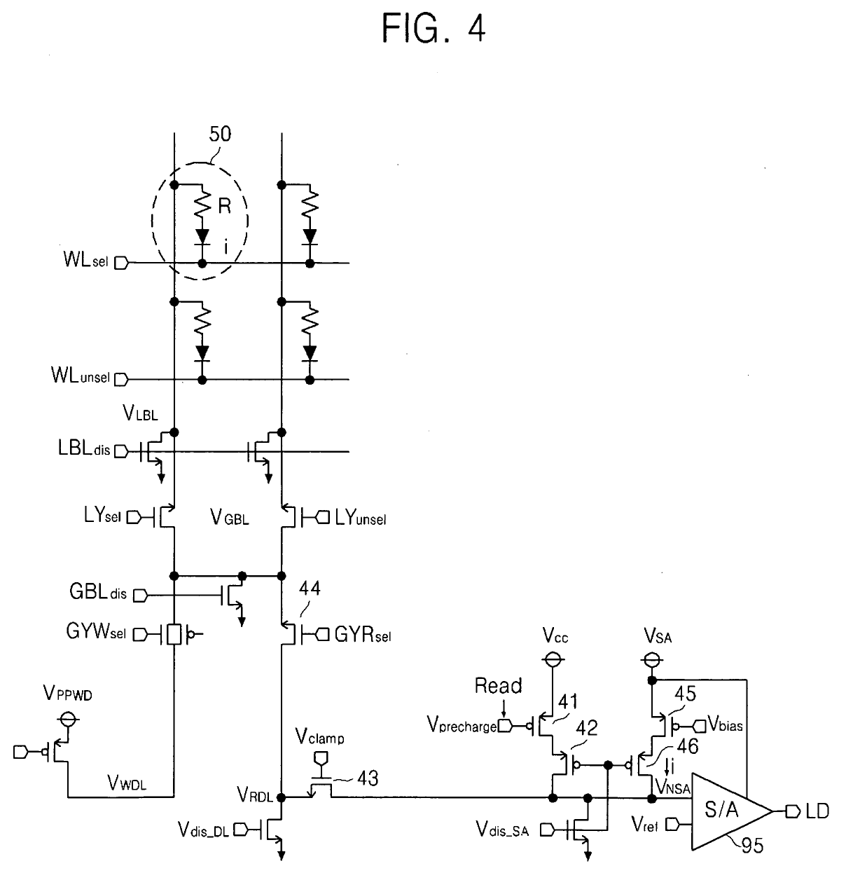

FIG. 4 is a circuit diagram of a non-volatile memory device according to an example embodiment.

During a read operation, a read signal “Read” may be input from an external device (e.g., a processor). In response to the read signal “Read”, a first transistor 41 is turned on. In other words, a gate voltage V_{precharge} of the first transistor 41 changes from “HIGH (e.g., V_{cc})” to “LOW (e.g., 0)” and the first transistor 41 is turned on. A second transistor 42 is also turned on, may be around the same time as the first transistor 41 or at a different time. As a result, a sensing node voltage V_{NSA} may be approximately the same as a first power supply voltage V_{cc}. A node voltage V_{RDL} is around “V_{clamp}-Vth.” In addition, a fourth transistor 44 may select a bit line used for reading a data cell. A word line may be selected from a plurality of word lines by, for instance, turning on a diode by changing a voltage WLₛₑₗ from “HIGH (e.g., V_{cc})” to “LOW (e.g., 0),” thereby causing a current “i” to flow through a selected memory cell 50.

Thereafter, the gate voltage V_{precharge} of the first transistor 41 may change from “LOW (e.g., 0)” to “HIGH (e.g., V_{cc})” and the first transistor 41 may be turned off. As a result, a supply path of the voltage V_{cc} is interrupted. As a result, the current “i” may be required to be supplied from a path formed by a fifth transistor 45 and a sixth transistor 46 in order to maintain the current “i” flowing in the selected memory cell 50. As the resistance of the selected memory cell 50 increases, the current “i” flowing in the diode decreases. As a result, a relatively small amount of current “i” may be supplied from the fifth transistor 45 and the sixth transistor 46, as mentioned above. Therefore, the sensing node voltage V_{NSA} may increase.

Contrarily, when the resistance value of the selected memory cell 50 decreases, the current “i” flowing in the diode increases. As a result, a large amount of the current “i” may be supplied from the path formed by the fifth transistor 45 and the sixth transistor 46, and therefore, the sensing node voltage V_{NSA} decreases. In other words, when the resistance value of the memory cell 50 increases, the sensing node voltage V_{NSA} of a sense amplifier circuit 95 also increases. When the resistance value of the memory cell 50 decreases, the sensing node voltage V_{NSA} of a sense amplifier circuit 95 also decreases. Consequently, the resistance value of a memory cell and the sensing node voltage V_{NSA} are in one-to-one correspondence, and therefore, the resistance variation of a data cell can be identified by comparing the sensing node voltage V_{NSA} with a reference voltage V_{ref}.

In addition, a variation in resistance of memory cell 50 may also be identified by adjusting a gate bias voltage V_{bias} of the fifth transistor 45. For instance, when the gate bias voltage V_{bias} of the fifth transistor 45 increases, a channel for passage of current in the fifth transistor 45 is reduced, and therefore, the current “i” decreases. The sensing node voltage V_{NSA} decreases due to the decreased current “i”. As such, according to an example embodiment, resistance variation may be identified based on the sensing node voltage V_{NSA} or the gate bias voltage V_{bias} of the fifth transistor 45.

FIG. 5 illustrates setting a reference voltage for programming a reference cell according to an example embodiment. Referring to FIGS. 4 and 5, a resistance variation may be identified based on the gate bias voltage V_{bias} of the fifth transistor 45 and resistance variations 21 through 23 of the reference cells may also be set based on the gate bias voltage V_{bias} of the fifth transistor 45.

For instance, a bias voltage V_{bias}_Ref2L_L corresponding to a minimum resistance of a resistance range of the second reference resistance variation 22 may be determined, given a bias voltage V_{bias}_D00_H corresponding to a maximum resistance of a resistance range of the first resistance variation 11 and a read margin ΔV. Similarly, a bias voltage V_{bias}_Ref2L_H corresponding to a maximum resistance in the resistance range of the second reference resistance variation 22 may be determined, given a bias voltage V_{bias}_D01_L corresponding to a minimum resistance in a resistance range of the second resistance variation 12 and the corresponding read margin ΔV. Bias voltages corresponding to resistance ranges of the first and third reference resistance variations 21 and 23 may be determined in a similar manner.

In addition, a non-volatile memory device, according to an example embodiment, may perform verification to check whether a memory cell has entered a resistance variation to be programmed based on a bias voltage.

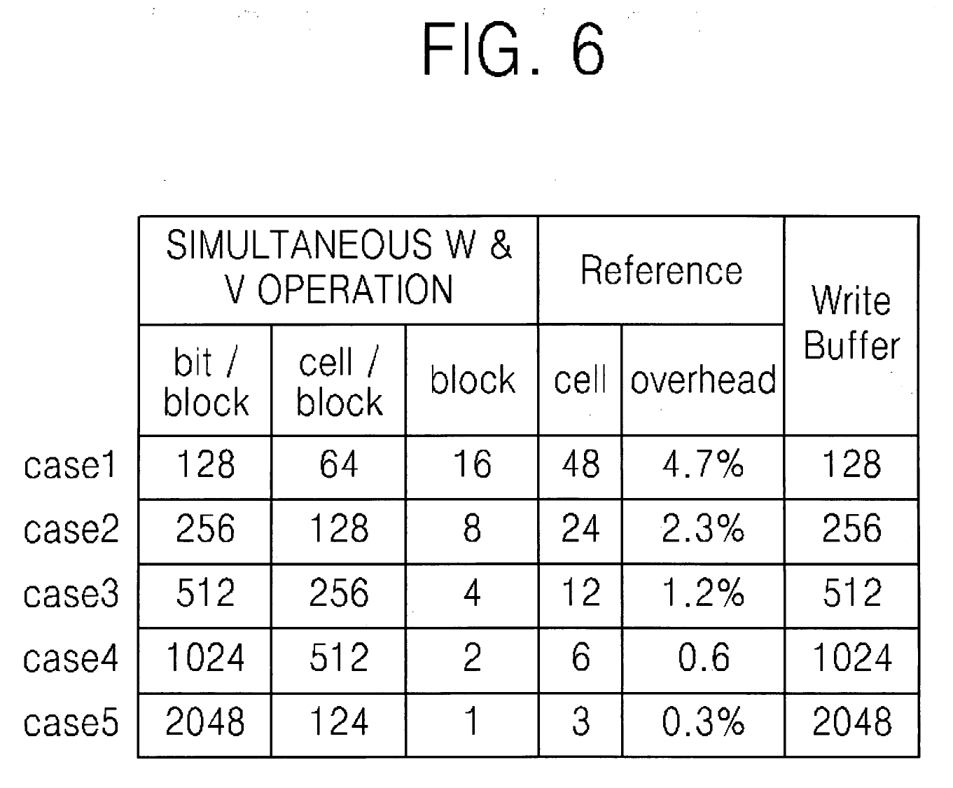

FIG. 6 shows information about the number of reference cells, overhead, write buffer, time, and read current in experimental cases when a unit of simultaneous write and verify (W & V) operation changes in a non-volatile memory device according to an example embodiment. For ease of description, a memory block in the non-volatile memory device has a size of 1 k (1024 bits)×1 k (1024 bits).

As described above, the non-volatile memory device may perform a program or write operation, a verify operation, and a read operation in a word line unit. Alternatively, the unit of the simultaneous W & V operation may be arbitrarily set, as illustrated in FIG. 6. For instance, as in a fifth experimental case (Case5), when all of 1024 memory cells connected to a single word line are subject to a simultaneous W & V operation and 3 reference cells are used, overhead is 3/1024*100=0.3%. In addition, since 1024 cells are simultaneously processed and each cell may be implemented by a 2-bit memory cell, a buffer having a size of 2048 (=1024×2) bits is needed. As in a first experimental case (Case1), when 1024 cells, divided into 16 blocks, are connected to a single word line and the resultant 64 (=1024/16) memory cells are subjected to the simultaneous W & V operation, 48 (=3×16) reference cells are needed and overhead is 48/1024*100=4.7%. In addition, since 64 cells are simultaneously processed and each cell may be implemented by a 2-bit memory cell, a buffer having a size of 128(=64×2) bits is needed. Similar discussion applies to Case2, Case3 and Case4.

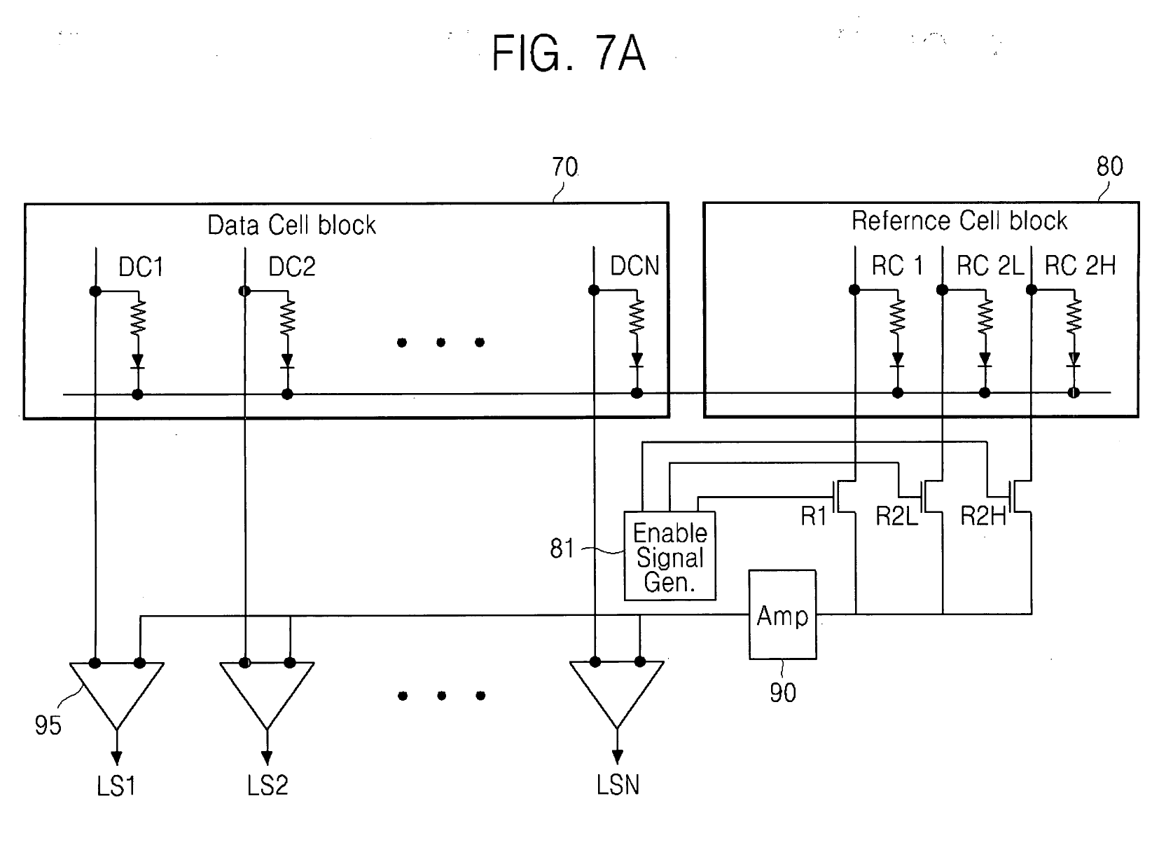

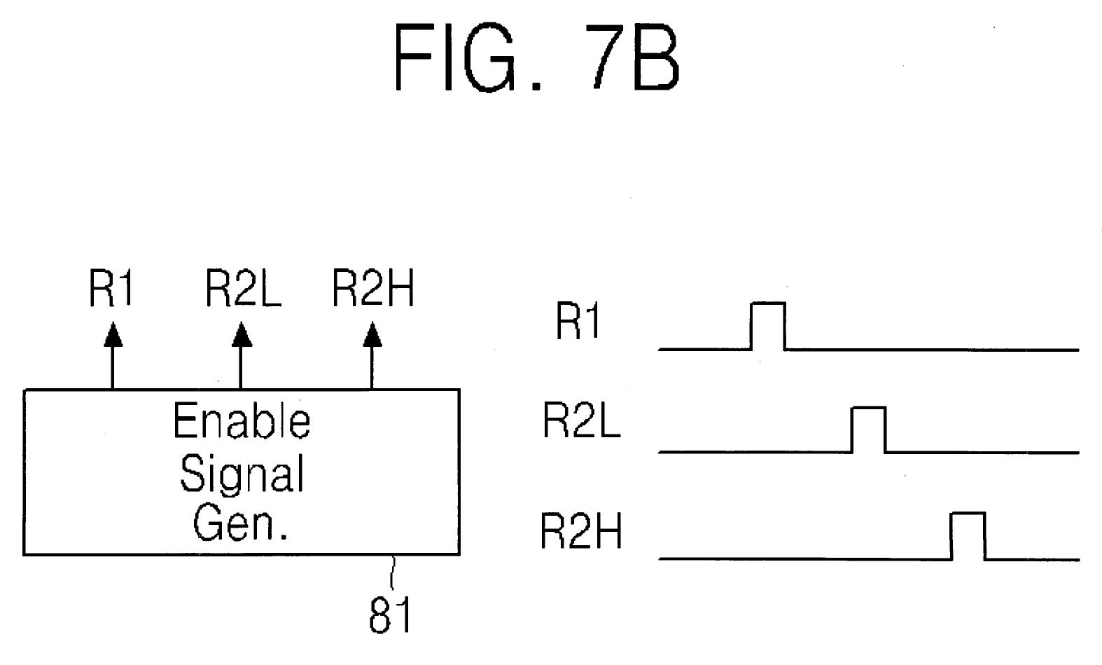

FIG. 7A illustrates the structure of a circuit for reading data programmed in a data cell in a non-volatile memory device according to an example embodiment. FIG. 7B is a timing diagram of clock signals R1, R2L, and R2H output from an enable signal generation circuit 81 included in the non-volatile memory device. The non-volatile memory device may also include a sense amplifier circuit 95 which compares a signal corresponding to a resistance value of one of a plurality of data cells with a signal corresponding to a resistance value of one of a plurality of reference cells and outputs a logic signal based on the comparison result.

Referring to FIG. 7A, the sense amplifier circuit 95 may be connected to a bit line. One of input terminals of the sense amplifier circuit 95 may be connected to one of a plurality of data cells DC1, DC2, . . . , DCN included in a data cell block 70 and another one of the input terminals of the sense amplifier circuit 95 may be connected to one of a plurality of reference cells RC1, RC2L, and RC2H included in a reference cell block 80. A memory cell and an input terminal of the sense amplifier circuit 95 are connected with each other in a manner as illustrated in FIG. 4.

Referring to FIGS. 4 and 7A, the resistance value of each memory cell may be identified by either the sensing node voltage V_{NSA} or the gate bias voltage V_{bias} of the fifth transistor 45, as described above with reference to FIG. 4. Accordingly, the resistance of a data cell can be compared with that of a reference cell by comparing a signal based on one of the data cells DC1 through DCN included in the data cell block 70 with a signal based on one of the reference cells RC1, RC2L, and RC2H included in the reference cell block 80.

It is required that a signal including resistance information of each reference cell included in the reference cell block 80 be sequentially input to the sense amplifier circuit 95. For this reason, the non-volatile memory device may include the enable signal generation circuit 81 which enables a signal corresponding to the resistance value of each reference cell RC1, RC2L, or RC2H to be sequentially output to the sense amplifier circuit 95.

Referring to FIG. 7B, the enable signal generation circuit 81 may output enable signals R1, R2L, and R2H for selectively inputting the signal based on the resistance value of each reference cell RC1, RC2L, or RC2H. The enable signal generation circuit 81 may output the enable signals R1, R2L, and R2H at different times, thereby allowing the enable signals R1, R2L, and R2H to be sequentially input to the sense amplifier circuit 95. Alternatively, the output timing of the enable signals R1, R2L, and R2H may be adjusted such that a signal corresponding to the resistance value of a reference cell (for example, RC1 in FIG. 7A) having an intermediate resistance variation is first output to the sense amplifier circuit 95.

FIG. 7B shows an example where a signal based on the first reference cell RC1, a signal based on the second reference cell RC2L, and a signal based on the third reference cell RC2H are sequentially output to the sense amplifier circuit 95. However, the signals may not be necessarily output in the order illustrated. Alternatively, three sense amplifier circuits 95 may be connected in parallel to a bit line so that the signal based on the first reference cell RC1, the signal based on the second reference cell RC2L, and the signal based on the third reference cell RC2H are simultaneously output to the three sense amplifier circuits 95, respectively. In addition, a large load is incurred when a signal corresponding to the resistance value of each reference cell RC1, RC2L, or RC2H is input to a plurality of sense amplifier circuits 95, and therefore, the signal may be amplified using an amplifier 90 before being transmitted to the sense amplifier circuits 95 to achieve improved reading.

The sense amplifier circuits 95 may compare a signal received from the data cell block 70 with a signal received from the reference cell block 80 and output logic signals LS1, LS2, . . . , LSN based on the comparison result. For instance, when resistance values are compared using the sensing node voltage V_{NSA}, each of the sense amplifier circuits 95 may compare the sensing node voltage. V_{NSA} corresponding to the resistance value of one of a plurality of data cells with the reference voltage V_{ref} corresponding with the resistance value of one of a plurality of reference cells and output a corresponding one of the logic signals LS1 through LSN based on the comparison result. When the sensing node voltage V_{NSA} is greater than the reference voltage V_{ref}, the sense amplifier circuits 95 may output the logic signals LS1 through LSN having a first level (e.g., a high level or “1”). When the sensing node voltage V_{NSA} is less than the reference voltage V_{ref}, the sense amplifier circuits 95 may output the logic signals LS1 through LSN having a second level (e.g., a low level or “0”).

With reference to FIGS. 1 and 7A, when the sense amplifier circuit 95 outputs “0” after comparing a signal based on the first data cell DC1 with a signal based on the first reference cell RC1, outputs “1” after comparing the signal based on the first data cell DC1 with a signal based on the second reference cell RC2L, and outputs “0” after comparing the signal based on the first data cell DC1 with a signal based on the third reference cell RC2H, it can be inferred that the first data cell DC1 is programmed to have the second resistance variation 12.

Accordingly, since each of the resistance variations of reference cells is positioned between resistance variations of data cells, a level state programmed to a data cell can be easily identified regardless of the change in resistance brought about by the change in time or temperature.

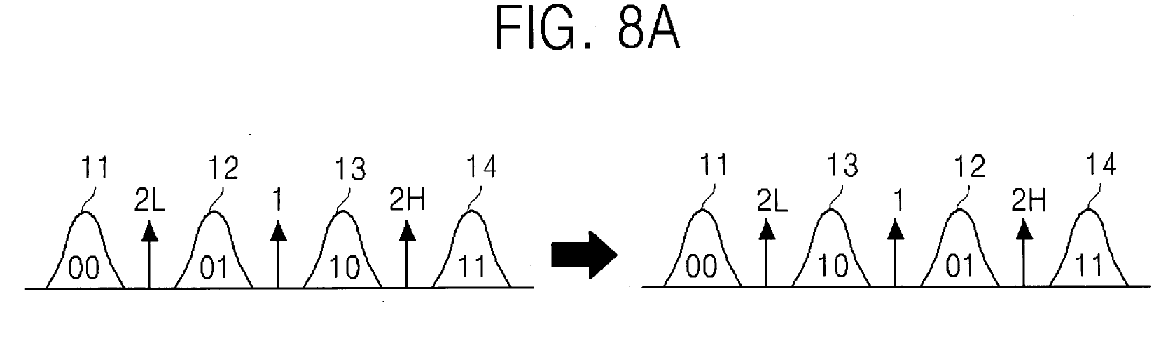

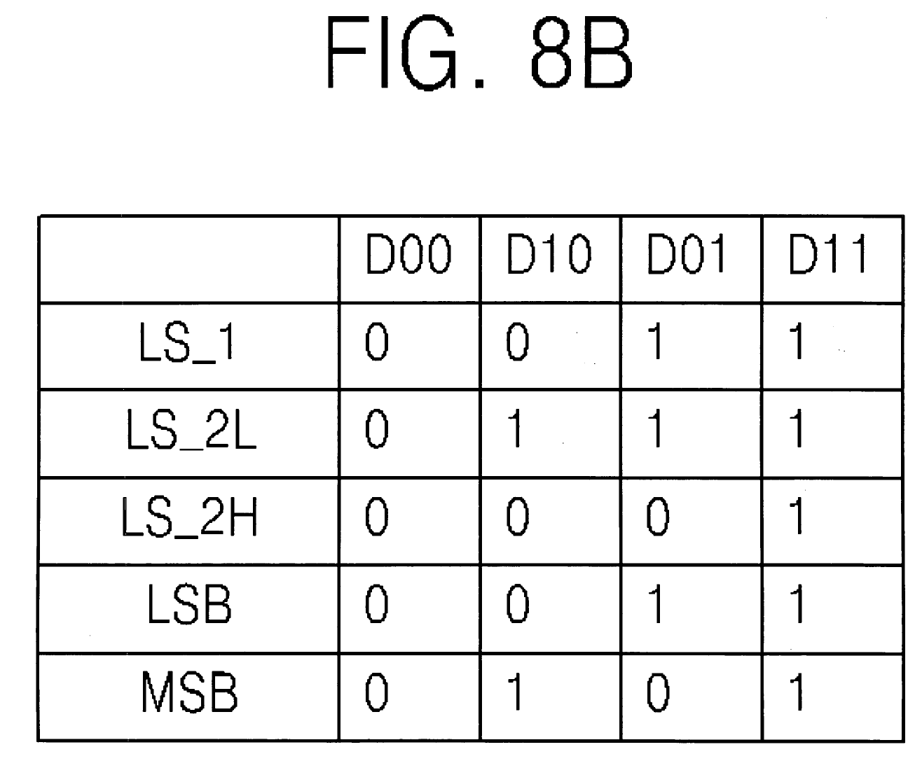

FIGS. 8A and 8B illustrate a method of reading data by interchanging resistance variations in a non-volatile memory device, according to an example embodiment. In the example embodiment illustrated in FIGS. 7A and 7B, three logic signals output from the sense amplifier circuit 95 are analyzed to identify a data level programmed to a data cell. In the example embodiment illustrated in FIGS. 8A and 8B, a Boolean function is used to identify the data level programmed to the data cell.

As illustrated in FIG. 8A, identification of the data level can be relatively easy by interchanging the positions of the second resistance variation 12 and the third resistance variation 13. The least significant bit (LSB) of the data level of the data cell can be calculated by comparing a signal based on the data cell with a signal based on the first reference cell RC1.

In the table illustrated in FIG. 8B, LS_1 denotes a logic signal resulting from comparing a signal based on a data cell with a signal based on the first reference cell RC1, LS_2L denotes a logic signal resulting from comparing the signal based on the data cell with a signal based on the second reference cell RC2L, and LS_2H denotes a logic signal resulting from comparing the signal based on the data cell with a signal based on the third reference cell RC2H. The LSB of multiple levels of the data cell can be calculated based on the logic signal LS_1 using Equation (1):

LSB=LS_{—}1. (1)

The most significant bit (MSB) of the multiple levels of the data cell can be calculated based on the logic signals LS_2L and LS_2H using Equation (2):

MSB=LS_{—}1 XOR (LS_{—}2L XOR LS_{—}2H). (2)

Accordingly, when a logic circuit implementing the logic table of FIG. 8B is disposed at an output terminal of the sense amplifier circuit 95, the level state of the data cell can be identified.

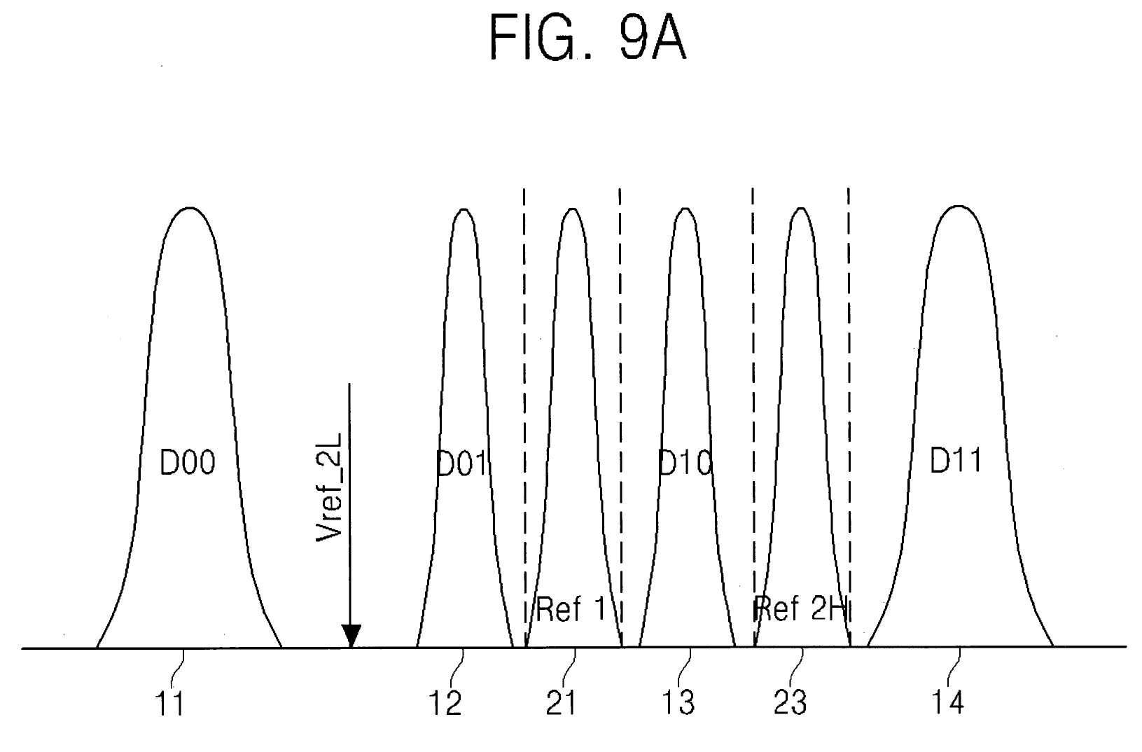

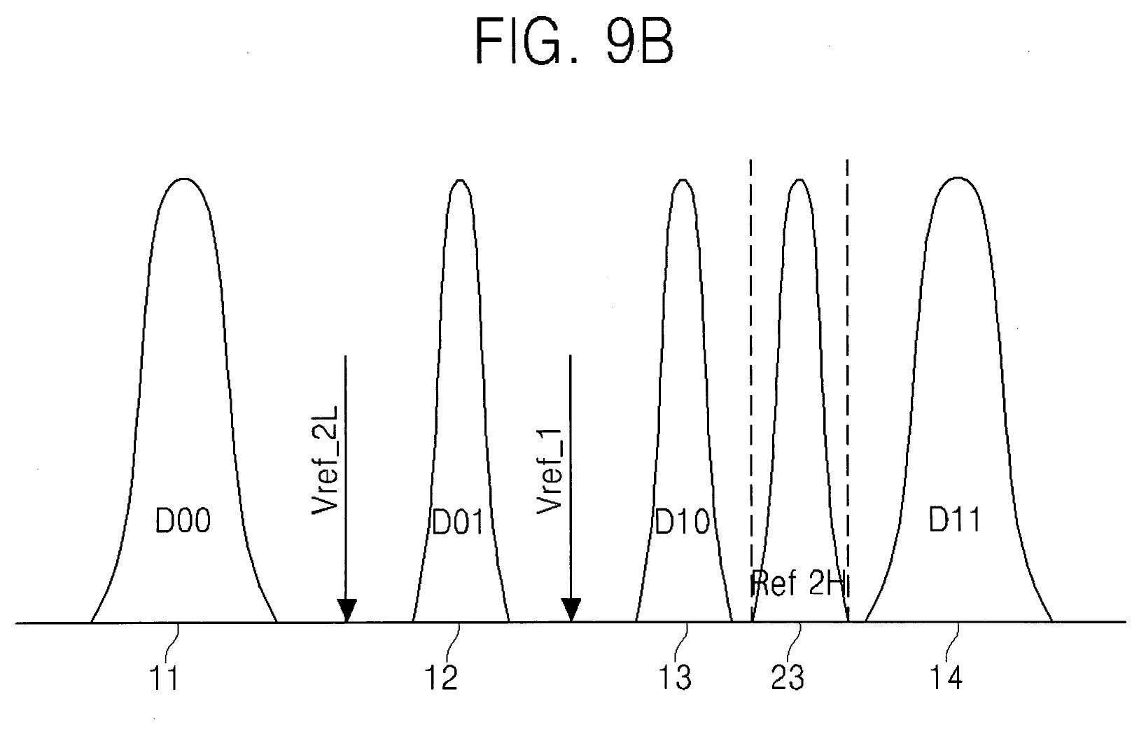

FIGS. 9A and 9B illustrate a method of reducing overhead, according to an example embodiment. As described above with reference to FIG. 6, an overhead may be incurred when reference cells are used in program and read operations. A partial reference cell may be used in order to reduce the overhead.

Referring to FIGS. 1 and 9A, the change in resistance with time or due to change in temperature increases as a resistance value increases. Accordingly, a reference cell block may exclude the second reference cell 22 having the least change in resistance. To compensate for the change in resistance of the first and second resistance variations 11 and 12 due to change in temperature, a second reference voltage Vref_2L corresponding to the second reference cell 22 may be changed. As a result, the overhead may be reduced by about ⅓.

Alternatively, referring to FIGS. 1 and 9B, the reference cell block may exclude two reference cells, the second reference cell 22 and the first reference cell 21 having the least change in resistance with time or due to change in temperature. To compensate for the change in resistance of the first and second resistance variations 11 and 12 due to change in temperature or the second and third resistance variations 12 and 13 due to change in temperature, the second reference voltage V_{ref} 2L corresponding to the second reference cell 22 and a first reference voltage V_{ref} 1 corresponding to the first reference cell 21 may be changed. As a result, the overhead may be reduced by about ⅔.

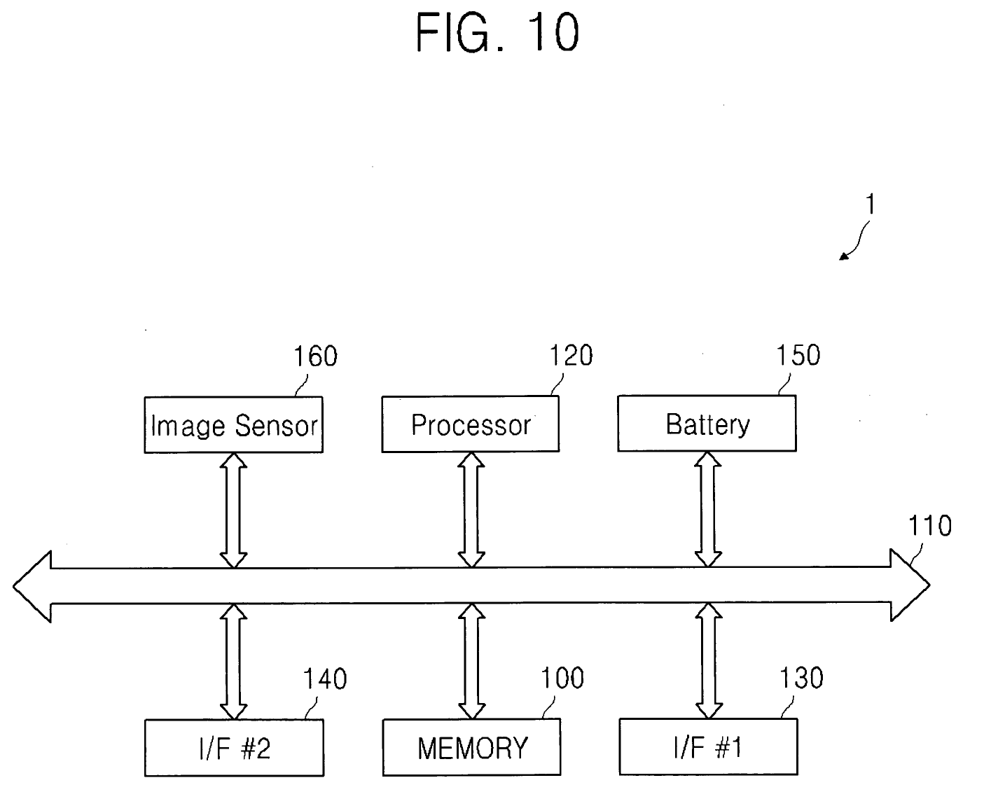

FIG. 10 is a block diagram of a storage system 1 including a non-volatile memory device 100 according to an example embodiment. The storage system 1 may include the non-volatile memory device 100 and a processor 120 connected to a system bus 110. The processor 120 may generate a control signal for controlling a program (or write), read or verify operation of the non-volatile memory device 100. Accordingly, a control block (not shown) of the non-volatile memory device 100 may perform the program, read or verify operation in response to the control signal output from the processor 120.

If the storage system 1 is implemented as a portable device, the storage system 1 may also include a battery 150 supplying operating power to the non-volatile memory device 100 and the processor 120. The portable device may be a portable computer, a digital camera, a personal digital assistant (PDA), a cellular telephone, an MP3 player, a portable multimedia player (PMP), an automotive navigation system, a memory card, a system card, a game machine, an electronic dictionary, a solid state disk or the like.

The storage system 1 may also include an input/output unit 130, enabling the storage system 1 to transmit and receive data to and from an external data processing device. If the storage system 1 is implemented as a wireless system, the storage system 1 may also include a wireless interface 140. The wireless interface 140 may be connected with the processor 120 and may transmit and receive data through the system bus 110 to and from an external wireless device via a wireless connection. The wireless system may be a wireless device such as a PDA, a portable computer, a wireless telephone, a pager, or a digital camera; a radio-frequency identification (RFID) reader; an RFID system or the like. Additionally, the wireless system may be a wireless local area network (WLAN) system or a wireless personal area network (WPAN) system. The wireless system may also be a cellular network.

If the storage system 1 is implemented as an image pick-up device, the storage system 1 may also include an image sensor 160 which may convert an optical signal into an electrical signal. The image sensor 160 may be an image sensor using a charge-coupled device (CCD) or a complementary metal-oxide semiconductor (CMOS) image sensor. The storage system 1 may be a digital camera or a cellular phone equipped with a digital camera. In addition, the storage system 1 may be a satellite system equipped with a camera.

According to an example embodiment, a reference cell is efficiently realized, so that a relatively large sensing margin may be secured with respect to resistance drift and temperature change. In addition, the change in resistance brought by temperature or time change is efficiently compensated for during data reading, so that the reliability of a data storage system may be increased.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A non-volatile memory device comprising:
a plurality of data cells, each data cell of the plurality of data cells programmed to have a first resistance variation among a plurality of first resistance variations; and
a plurality of reference cells, each reference cell of the plurality of reference cells programmed to have a second resistance variation among a plurality of second resistance variations.

2. The non-volatile memory device of claim 1, wherein when each of the data cells is an N-bit multi-level cell, each reference cell is programmed to have the second resistance variation among (2^{N}−1) second resistance variations, where N is a natural number.

3. The non-volatile memory device of claim 2, wherein each reference cell is programmed to have different second resistance variations.

4. The non-volatile memory device of claim 1, wherein at least one second resistance variation is present between two adjacent first resistance variations.

5. The non-volatile memory device of claim 1, wherein the data cells and the reference cells are resistive memory cells.

6. The non-volatile memory device of claim 1, wherein the data cells and the reference cells are simultaneously programmed.

7. The non-volatile memory device of claim 1, further comprising a sense amplifier circuit configured to compare a signal corresponding to a resistance of at least one data cell with a signal corresponding to a resistance of at least one reference cell and to output a logic signal based on the comparison result.

8. The non-volatile memory device of claim 7, further comprising an enable signal generation circuit configured to generate at least one enable signal to sequentially output the signal corresponding to the resistance of at least one reference cell to the sense amplifier circuit.

9. The non-volatile memory device of claim 8, wherein the enable signal generation circuit controls an output timing of at least one enable signal to first output the signal corresponding to the resistance of the reference cell having an intermediate resistance variation to the sense amplifier circuit.

10. A storage system comprising:
a non-volatile memory device of claim 1; and
a processor configured to control operations of the non-volatile memory device.

11. The storage system of claim 10, further comprising a wireless interface connected with the processor.

12. The storage system of claim 10, further comprising an input/output interface connected with the processor.

13. The storage system of claim 10, wherein the data cells and the reference cells are resistive memory cells.
